(19) United States
(12) Patent Application Publication
(10) Pub. No.: US 2024/0178075 A1
(43) Pub. Date: May 30, 2024

(54) METHOD FOR TESTING A WAFER AND WAFER

(71) Applicant: ams-OSRAM International GmbH, Regensburg (DE)

(72) Inventor: Ivar Tangring, Regensburg (DE)

(21) Appl. No.: 18/551,802

(22) PCT Filed: Mar. 1, 2022
(86) PCT No.: PCT/EP2022/055100

§ 371 Date: Sep. 21, 2023

(30) Foreign Application Priority Data
Apr. 8, 2021 (DE) 10 2021 108 756.2

(51) Int. Cl. H01L 21/66; G01R 31/26; H01L 21/324

(52) U.S. Cl. CPC H01L 22/12; G01R 31/2601; H01L 21/324

(57) ABSTRACT

In an embodiment a method includes providing a wafer with a semiconductor layer sequence arranged on a substrate, attaching at least one first contact element to a main surface of the semiconductor layer sequence facing away from the substrate, attaching at least one second contact element to the main surface of the semiconductor layer sequence at a distance to the first contact element and applying a first electrical potential to the first contact element and a second electrical potential to a second contact element, wherein the first electrical potential and the second electrical potential are different from each other, wherein, by locally annealing the semiconductor layer sequence, a first contact region is formed in a region of the first contact element and a second contact region, which is spaced apart from the first contact region, is formed in a region of the second contact element.

### CROSS-REFERENCE TO RELATED APPLICATIONS

This patent application is a national phase filing under section 371 of PCT/EP2022/055100, filed Mar. 1, 2022, which claims the priority of German patent application 102021108756.2, filed Apr. 8, 2021, each of which is incorporated herein by reference in its entirety.

### TECHNICAL FIELD

A method for performing a functional test on a wafer is specified.

### SUMMARY

Embodiments provide an efficient method for testing the functionality of a wafer in which the wafer is impaired as little as possible. Further embodiments provide a wafer on which such a method can be carried out.

According to at least one embodiment of the method, the wafer is provided in a first step of the method. The wafer comprises a substrate and a semiconductor layer sequence arranged on the substrate. The semiconductor layer sequence is configured, for example, for generating electromagnetic radiation. For this purpose, the semiconductor layer sequence preferably comprises an active zone between a first semiconductor layer and a second semiconductor layer. The first semiconductor layer is, for example, n-doped and the second semiconductor layer is, for example, p-doped. For example, the semiconductor layer sequence is based on a III-V compound semiconductor system. Preferably, the semiconductor layer sequence is based on one of the following III-V compound semiconductor systems: GaN, InGaN, GaP, InGaAlP.

In particular, the substrate is a growth substrate for the semiconductor layer sequence. For example, the substrate comprises sapphire or is formed from sapphire.

According to at least one embodiment of the method or its embodiment described above, the substrate is an electrically conductive substrate. In this case, the substrate is formed, for example, with a semiconductor material such as GaAs. This is the case, for example, when the semiconductor layer sequence is based on InGaAlP.

According to at least one embodiment of the method or one of its embodiments described above, at least one first contact element is attached to a main surface of the semiconductor layer sequence facing away from the substrate. For example, the first contact element is attached directly to the main surface. For example, the contact element comprises one or more metals. The metals are, for example, platinum, titanium, chromium, or gold.

The first contact element is applied, for example, by means of vapor deposition or deposition. The first contact element is arranged, for example, in view of the main surface with a width between 30 μm and 50 μm inclusive at the main surface.

For example, a shadow mask is used to apply the first contact element.

Optionally, at least one second contact element is arranged on the main surface. The second contact element is preferably arranged at a distance from the first contact element. The second contact element comprises, for example, the same materials and dimensions as the first contact element and is applied using the same methods. Preferably, the first contact element and the second contact element are applied in a common process step.

In one embodiment of the method or one of its embodiments described above, the semiconductor layer sequence is annealed in a region at the main surface before the first and, if applicable, the second contact element are applied. The annealing takes place at least in a region in which the first contact element and, if applicable, the second contact element is or are subsequently applied. The region at the main surface is formed, for example, connected, in particular simply connected. For example, the region in which annealing is carried out comprises the entire main surface. It is also possible that the entire semiconductor layer sequence or the entire wafer is annealed.

The annealing is for example a thermal annealing. For example, the semiconductor layer sequence at least in the region where the first contact element is subsequently arranged or the wafer is heated to a high temperature during thermal annealing. The temperature is, for example, between about 300° C. and about 400° C.

In one embodiment of the method or one of its embodiments described above, an electrical contact layer is applied on the main surface of the semiconductor layer sequence before the semiconductor layer sequence is annealed. The annealing process establishes a low-resistance electrical contact between the contact layer and the semiconductor layer sequence. The first and optionally the second contact element are applied to a side of the contact layer facing away from the semiconductor layer sequence. Preferably, the contact layer is removed in places so that there is no electrical connection between the first and second contact elements via the contact layer.

In an alternative embodiment of the method, the semiconductor layer sequence is annealed locally. In this case, the semiconductor layer sequence is annealed in the region of the first contact element and, if applicable, in the region of the second contact element. The local annealing is in particular a thermal annealing. The present embodiment represents in particular an alternative to the embodiment in which the semiconductor layer sequence is annealed at least in regions before the first contact element is attached.

According to at least one embodiment of the method or one of its embodiments described above, a first electrical potential is applied to a first contact element. A second electrical potential is optionally applied to the second contact element or to the substrate. The first electrical potential and the second electrical potential are selected to be different from each other. By applying the electrical potentials, a functionality of the wafer or the semiconductor layer sequence is tested, for example. If the semiconductor layer sequence is, for example, a semiconductor layer sequence configured to generate electromagnetic radiation, electromagnetic radiation is generated by applying the first and second potentials.

When the second electrical potential is applied to the substrate, the substrate is an electrically conductive substrate.

If the second electrical potential is applied to a second contact element arranged at a main surface of the semiconductor layer sequence, the first or second electrical potential is selected such that a breakthrough is generated in at least one layer of the semiconductor layer sequence. For example, the first and second contact elements are arranged at a p-type layer of the semiconductor layer sequence. For example, the first electrical potential is selected such that the breakthrough is generated in a region of the p-type layer and the active zone that is covered by the first contact element when viewed from above the main surface. Electrons can pass through the breakthrough from the first contact element into an n-type layer of the semiconductor layer sequence. In particular, the n-type layer is arranged between the active zone and the substrate. By applying the second potential to the second contact element, p-type charge carriers enter the p-type layer. In this case, the first contact element forms a cathode and the second contact element forms an anode. This makes it possible to supply an active zone of the semiconductor layer sequence with current and thus generate electromagnetic radiation.

In at least one embodiment of the method, a wafer having a semiconductor layer sequence arranged on a substrate is provided. A first contact element is applied to a main surface of the semiconductor layer sequence facing away from the substrate. The semiconductor layer sequence is annealed prior to the application of the first contact element in a region at the main surface, which region comprises at least the region in which the contact element is subsequently applied. A first electrical potential is applied to the first contact element. A second electrical potential is applied to an optional second contact element of the semiconductor layer sequence or to the substrate. The first electrical potential and the second electrical potential are selected to be different from each other.

In at least one alternative embodiment of the method, a wafer having a semiconductor layer sequence arranged on a substrate is provided. At least a first contact element is provided on a main surface of the semiconductor layer sequence facing away from the substrate. The semiconductor layer sequence is locally annealed, the annealing occurring in the region of the first contact element. A first electrical potential is applied to the first contact element, and a second electrical potential is applied to a second contact element on the semiconductor layer sequence or on the substrate. The first electrical potential and the second electrical potential are selected to be different from each other.

To perform a functional test, especially a quick test, contacts are conventionally applied to the wafers through a shadow mask. The wafer is heat treated to establish an electrical contact between the contacts and the wafer. This is only done on a few wafers, for example between 10% and 20% of the total wafers processed. This is done under the assumption that wafers from the same processing process behave similarly in terms of their electrical and/or optical properties. The processing process is, for example, an epitaxial process in which a semiconductor layer sequence is grown. Subsequently, the epitaxially grown structures of the wafers are measured. Subsequently, the contacts can be removed and the wafer is further processed.

For example, the wafer is further processed into optoelectronic semiconductor chips for light-emitting diodes. The annealing by means of the heat treatment changes the electrical and/or optical properties of the tested wafer compared to the non-tested wafers. Semiconductor chips that emerge from the tested wafers typically have a higher forward voltage and thus poorer electrical and/or optical properties than semiconductor chips that originate from wafers that have not been tested.

For example, during further processing of the wafers into semiconductor chips, another thermal annealing is carried out. The wafers that have undergone a quick test are then heat treated twice as often as the remaining wafers. The double heat treatment leads, for example, to a degeneration of the semiconductor layer sequences and thus to an increased forward voltage of the resulting semiconductor chips.

The test method described here makes use of the idea of locally annealing the semiconductor layer sequence in regions of the contact elements. Thus, a low-resistance electrical contact with a low contact resistance is established between the contact elements and the semiconductor layer sequence without heating the entire wafer. This is achieved, for example, by optical excitation, whereby the contact elements are heated by absorption of radiation. The wafer, on the other hand, is transparent or substantially transparent to this radiation and does not heat up significantly.

One advantage is that the wafer is heat treated only in the region of the contact elements. Other parts of the wafer can be used for further processing into semiconductor chips without these regions of the wafer being altered compared to non-tested wafers. If the electrical contact elements on the wafer are selected accordingly, up to 99% of the tested wafer can be used without restriction for further processing, whereas with a conventional quick test the entire tested wafer may be unsuitable for further processing.

Another idea the present method is based on is to anneal the semiconductor layer sequence at least in some regions before applying the contact elements. In particular, an electrical contact layer is arranged on the main surface before annealing, and the contact elements are arranged on this layer after annealing. In particular, a layer is selected as the electrical contact layer which is also used in the subsequent further processing of the wafer, for example to produce semiconductor chips. In further processing, steps involving application of the contact layer and annealing of the wafer then do not have to be carried out. A second thermal annealing of the tested wafer is thus avoided. If the electrical contact elements on the wafer are selected accordingly, up to 99% of the wafer can be used without restriction for further processing.

Another advantage is that not only the functionality of the semiconductor layer sequence can be tested, but also a quality of the low-resistance contact between the contact layer and the semiconductor layer sequence.

According to at least one embodiment of the method, in which the semiconductor layer sequence is locally annealed, at least one second contact element is arranged on the main surface of the semiconductor layer sequence. The second contact element is arranged in particular at a distance from the first contact element. In this embodiment, the second electrical potential is applied to the second contact element.

According to at least one embodiment of the method, in which the semiconductor layer sequence is locally annealed and a second contact element is formed, a first contact region is formed in the region of the first contact element and a second contact region is formed in the region of the second contact element by means of local annealing of the semiconductor layer sequence. In particular, the first contact region and the second contact region are formed spaced apart from each other. The first/second contact region is at least partially covered by the first/second contact element in plan view. The first and second contact regions are in particular regions of the wafer in which the semiconductor layer sequence or the wafer is locally annealed.

The first contact region and/or the second contact region have, for example, a width, measured parallel to the main surface, between 50 μm and 100 μm inclusive. Alternatively or additionally, the width of the first/second contact region is at most twice as large as the width of the first/second contact element. Advantageously, only a small part of the wafer is annealed with such small contact regions.

According to at least one embodiment of the method, in which the semiconductor layer sequence is locally annealed, the local annealing is performed by means of radiation of a first wavelength range. The radiation of the first wavelength range comprises, for example, infrared radiation or visible light. The first wavelength range comprises, for example, wavelengths greater than 400 nm or greater than 450 nm. The first wavelength range and/or materials of the first and, if applicable, second contact elements are selected in particular such that the radiation is at least partially absorbed by the contact elements.

The first and/or the second contact element has, for example, an absorption coefficient of at least 0.6 or at least 0.7 or at least 0.8. The first and/or the second contact element has, for example, a reflection coefficient of at most 0.4 or at most 0.3 or at most 0.2.

The absorption of the radiation causes heating of the first/second contact element. The heating of the first/second contact element causes the local annealing of the semiconductor layer sequence, in particular in the first/second contact region.

A mean temperature of the semiconductor layer sequence in the first contact region and/or the second contact region is higher during annealing by, for example at least 50° C., than a mean temperature of the semiconductor layer sequence outside the first/second contact region. For example, the contact elements are heated to a temperature between 300° C. and 400° C. inclusive during annealing. For example, the semiconductor layer sequence or wafer has an average temperature of less than 300° C. or less than 200° C. or less than 100° C. outside the first/second contact region during irradiation with radiation of the first wavelength range.

For example, the irradiation of the first wavelength range takes place over a time period of at most one second or at most one minute or at most one or more hours. Preferably, the wafer is irradiated with unfocused radiation. For example, the wafer is irradiated with a flash light.

According to at least one embodiment of the method, in which the semiconductor layer sequence is locally annealed by means of radiation of the first wavelength range, the first wavelength range is selected such that the semiconductor layer sequence is transparent to radiation of the first wavelength range. In particular, the entire wafer is transparent to radiation of the first wavelength range. By “transparent” is meant here and in the following in particular that the substrate and/or the wafer absorbs at most 5% or at most 10% of the radiation in question.

According to at least one embodiment of the method, in which the semiconductor layer sequence is locally annealed by means of radiation of the first wavelength range, the main surface is irradiated with radiation of the first wavelength range from a direction of a side of the semiconductor layer sequence facing away from the contact elements. That is, radiation of the first wavelength range first passes the substrate and the semiconductor layer sequence before it impinges the first and second contact elements. In this embodiment, the substrate and the semiconductor layer sequence are transparent to radiation of the first wavelength range.

According to at least one embodiment of the method, in which the semiconductor layer sequence is locally annealed, an intermediate layer is formed between the first contact element and the semiconductor layer sequence. Thereby, for example, material for the intermediate layer is deposited as an electrical contact layer on the main surface of the semiconductor layer sequence.

The contact layer comprises, for example, a transparent conductive oxide, for example indium tin oxide, ITO for short. The contact layer is applied, for example, by means of sputtering. The electrical contact layer is applied, for example, with a thickness between 10 nm and 20 nm inclusive. In view of the main surface, the electrical contact layer preferably completely covers the semiconductor layer sequence.

The first contact element is applied to the contact layer in places, for example. Optionally, a second contact element is applied to the contact layer in places. The first and optionally the second contact element are applied, for example, using one of the methods described above.

The contact layer is removed, for example, in regions that are free of the first contact element when viewed from the main surface, thus forming the intermediate layer. The intermediate layer is completely covered by the contact elements, for example, when in view of the main surface.

In semiconductor chips manufactured from the wafer, a contact layer of transparent conductive oxide is often used to establish direct electrical contact between the semiconductor layer sequence and further contact structures. If an intermediate layer described here is arranged, the functional test described here can advantageously be used to test not only the functionality of the semiconductor layer sequence but also a contact resistance between the intermediate layer and the semiconductor layer sequence.

According to at least one embodiment of the method, in which the semiconductor layer sequence is annealed at least in regions before application of contact elements, a contact layer is applied to the main surface. In particular, the contact layer is applied before the annealing is carried out. The contact layer comprises, for example, a transparent conductive oxide, for example ITO. The contact layer is applied, for example, by means of sputtering. The electrical contact layer is applied, for example, with a thickness between 10 nm and 20 nm inclusive.

The first contact element is applied to the contact layer in places.

In a further step, a protective layer followed by a mask layer is applied to a side of the contact layer facing away from the semiconductor layer sequence. The protective layer comprises, for example, Al₂O₃ and serves, inter alia, to protect the electrical contact layer. The protective layer is applied, for example, by means of atomic layer deposition or ALD for short. The protective layer is applied, for example, with a thickness between 30 nm and 40 nm inclusive.

In a further step, the mask layer is structured, whereby at least one opening is formed in the mask layer. The first contact element is not covered by the mask layer in the opening. The protective layer is exposed in the opening.

In a further method step, the protective layer is removed in regions of the opening so that the contact layer and the first contact element are exposed. The protective layer is removed by etching, for example. A wet chemical etching method is used, for example. For example, H₃PO₄ is used as an etchant.

In a further method step, the contact layer is removed within the opening in regions that are free of the first in view of the main surface. The contact layer is removed by etching, for example. For example, a wet chemical etching method is used. For example, HCl is used as an etchant.

If applicable, the second contact element is formed simultaneously with the first contact element by means of the same process.

In a further method step, the mask layer is removed at least partially, in particular completely. For example, the mask layer is removed with an organic solvent or by means of heat and oxygen or oxygen plasma, also known as ashing.

In this embodiment of the method, contact elements are formed which are not electrically connected to each other via the contact layer. Outside regions of the contact elements, the main surface is covered by a contact layer and the protective layer. During further processing of the wafer, for example to produce certain semiconductor chips for light-emitting diodes, such a contact layer and protective layer are also conventionally applied and the wafer is thermally annealed. When the wafer is further processed into such semiconductor chips, these steps can be dispensed with and thus also further thermal annealing.

According to at least one embodiment of the method, in which the semiconductor layer sequence is annealed at least in regions prior to the attachment of contact elements, a photoresist is used as mask layer. The photoresist is patterned by means of radiation of a second wavelength range. Radiation of the second wavelength range is thereby reflected at the first contact element contact element. For example, the photoresist is exposed to radiation of the second wavelength range and subsequently developed to structure the mask layer.

The radiation of the second wavelength range is, for example, UV radiation. Preferably, the second wavelength range comprises wavelengths of the near UV range. For example, the second wavelength range comprises wavelengths between 300 nm and 400 nm, inclusive.

For example, a so-called positive photoresist is used as a photoresist. With a positive photoresist, openings can be formed during development in regions where the photoresist has been exposed. In this case, radiation of the second wavelength range is preferably directed onto the main surface from the direction of the first contact element. Due to the reflection of the radiation of the second wavelength range at the first contact element, a region of the mask layer which covers the contact element in view of the main surface is exposed more than other regions of the photoresist. When the mask layer is developed, the openings are formed in the more strongly exposed regions. Since a locally increased exposure in the region of the later opening is achieved by the reflection at the first contact element, the wafer can be irradiated with radiation of the second wavelength range over a large area. Selective irradiation of the mask layer and/or focusing of the radiation of the second wavelength range is not necessary in this case.

If applicable, an opening in the mask layer in the region of the second contact element is produced by means of the same process simultaneously with the opening in the region of the first contact element.

According to at least one embodiment of the method, in which the mask layer is patterned by means of radiation of the second wavelength range, the radiation of the second wavelength range is selected such that the semiconductor layer sequence, in particular the entire wafer, is transparent to radiation of the second wavelength range.

According to at least one embodiment of the method, in which the mask layer is patterned by means of radiation of the second wavelength range, the radiation of the second wavelength range is irradiated from the direction of a side of the semiconductor layer sequence facing away from the mask layer. In this case, the semiconductor layer sequence and/or the substrate are transparent for radiation of the second wavelength range.

In this embodiment, a negative photoresist is preferably used for the mask layer. In the case of a negative photoresist, openings are preferably formed during development in regions of the photoresist that were not previously exposed or were exposed to a lesser extent than other regions of the photoresist. The irradiation of the radiation of the second wavelength range from the direction of a side of the semiconductor layer sequence facing away from the mask layer causes regions of the mask layer which, in view of the main surface, cover the first contact element to be shadowed by the first contact element. This means that the photoresist is hardly or only slightly exposed in this regions. When the mask layer is developed, the opening is formed in this region. Since a locally reduced exposure in the regions of the later opening is achieved by shading, the wafer can be irradiated over a large area with radiation of the second wavelength range. Selective irradiation of the mask layer and/or focusing of the radiation of the second wavelength range is not necessary in this case.

If applicable, an opening in the mask layer in the region of the second contact element is produced by means of the same process simultaneously with the opening in the region of the first contact element.

According to at least one embodiment of the method, in which a mask layer is deposited, the mask layer is thermally patterned. For this purpose, the semiconductor layer sequence is irradiated with radiation of a third wavelength range. The radiation of the third wavelength range is absorbed by the first contact element. The absorption causes in particular a heating of the first contact element. An absorption rate of the first contact element is, for example, at least five times as large as an absorption rate of the wafer.

The mask layer evaporates or melts or sublimates in the region covering the first contact element. The melting or evaporation or sublimation of the mask layer is in particular a consequence of the heating of the first contact element. In this embodiment, the mask layer is preferably formed with a material whose melting, vaporization or sublimation temperature is lower than 200° C. or lower than 300° C. The material is, for example, a thermoplastic.

Optionally, after evaporation or melting of the mask layer, the wafer is cleaned in the region of the resulting opening to remove residues of the mask layer in the opening. For example, an oxygen plasma is used for cleaning.

If applicable, an opening in the mask layer in the region of the second contact element is produced by means of the same process simultaneously with the opening in the region of the first contact element.

According to at least one embodiment of the method, in which the mask layer is thermally structured, the third wavelength range is selected such that the semiconductor layer sequence or the wafer is transparent for radiation of the third wavelength range. Advantageously, heating of the semiconductor layer sequence is thus kept low or avoided.

According to at least one embodiment of the method, in which the mask layer is thermally structured, the radiation of the third wavelength range is irradiated from a direction of a side of the semiconductor layer sequence facing away from the mask layer.

According to at least one embodiment of the method, in which the semiconductor layer sequence is locally annealed or in which an at annealing of the semiconductor layer sequence is carried out in places before the application of contact elements, all contact elements are removed in a further method step. For example, the contact elements are removed by etching. For example, a wet chemical etching method is used. For example, a mixture of hydrochloric acid and nitric acid, also known as aqua regia, is used as the etchant.

According to at least one embodiment of the method, in which the semiconductor layer sequence is locally annealed or which an at annealing of the semiconductor layer sequence is carried out in places before the application of contact elements, a position of each contact element on the main surface of the semiconductor layer sequence is selected by means of lithography or on the basis of a position marker. For example, this allows the first contact element to be selectively located in regions of the wafer that are not considered for further processing of the wafer. The position marker can be an OCR field, for example. If the first contact element is arranged on the main surface by means of lithography or by means of position markers, the contact element can be arranged with high precision. For example, the contact element itself can be used as a position marker during further processing of the wafer, for example into semiconductor chips. In this case, the first contact element is preferably not removed.

If applicable, a position of the second contact element is formed simultaneously with the first contact element using the same method.

Furthermore, a wafer is specified. In particular, the method described herein can be carried out on the wafer. That is, all features disclosed for the method are also disclosed for the wafer and vice versa.

The wafer comprises a substrate and a semiconductor layer sequence arranged on the substrate with a main surface facing away from the substrate. At least one electrical contact element is arranged on the main surface. The semiconductor layer sequence is locally annealed in a region of the first contact element. Alternatively, the semiconductor layer sequence is annealed at least in a region at the main surface, the region at the main surface comprising at least a region to which the first contact element is attached.

Further advantages and advantageous embodiments and further developments of the method result from the following exemplary embodiments shown in connection with the schematic drawings. Identical, similar and similarly acting elements are provided with the same references in the figures. The figures and the proportions of the elements shown in the figures with respect to one another are not to be regarded as true-to-scale. Rather, individual elements may be shown exaggeratedly large for better representability and/or for improved comprehensibility.

### BRIEF DESCRIPTION OF THE DRAWINGS

In the Figures:

FIGS. 1 to 9 show procedural stages of a method for performing a functional test on a wafer 100, in which the semiconductor layer sequence is locally annealed, according to two embodiments;

FIGS. 10 to 19 show procedural stages of a method for performing a functional test on a wafer, in which the semiconductor layer sequence is annealed at least in regions before arranging contact elements, according to an embodiment example; and

FIGS. 20 to 22 show procedural stages of a method in which the semiconductor layer sequence is annealed at least in regions before the application of contact elements, according to further embodiments.

### DETAILED DESCRIPTION OF ILLUSTRATIVE EMBODIMENTS

The embodiments shown in the Figures are each sectional views in which a sectional plane is perpendicular to a main extension plane of the wafer 100.

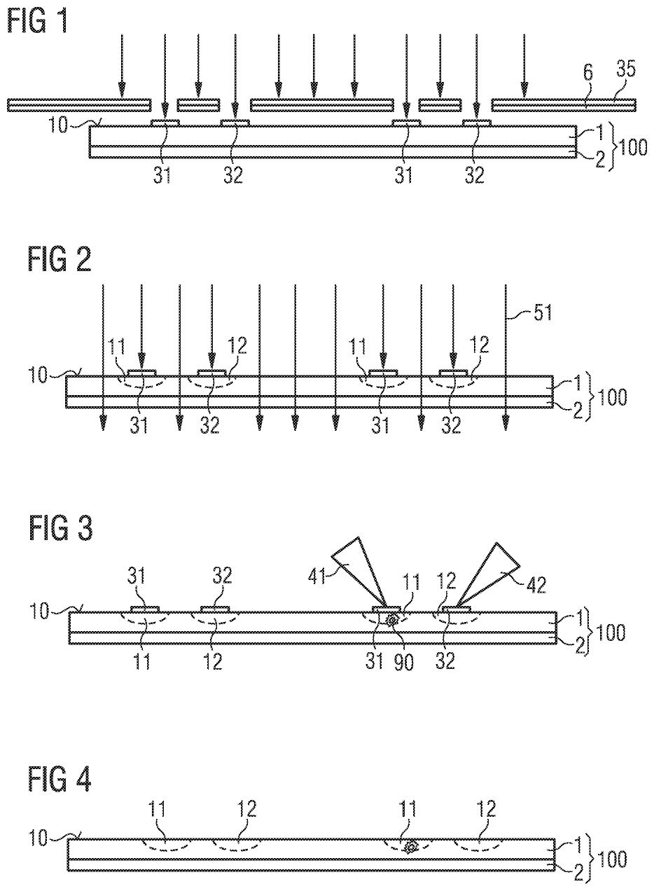

In the method illustrated in FIGS. 1 to 4, a wafer 100 comprising a substrate 2 on which a semiconductor layer sequence 1 is arranged is provided. The substrate 2 is a sapphire substrate. The semiconductor layer sequence 1 is epitaxially grown on the substrate 2, for example.

The semiconductor layer sequence 1 is configured to generate electromagnetic radiation, for example. The semiconductor layer sequence 1 includes an active zone between a first semiconductor layer and a second semiconductor layer. The semiconductor layer sequence 1 is based on a III-V semiconductor material, such as GaN or InGaN. The first semiconductor layer is, for example, an n-type GaN- or InGaN-based layer or layer sequence. The second semiconductor layer is, for example, a p-type GaN- or InGaN-based layer or layer sequence. The active zone is, for example, a GaN- or InGaN-based quantum well structure or multi quantum well structure.

A plurality of first contact elements 31 and a plurality of second contact elements 32 are arranged on a main surface 10 of the semiconductor layer sequence 1 (FIG. 1). The main surface 10 opposes the substrate 2.

The contact elements 31, 32 each comprise one or more metals. The metals are, for example, titanium, chromium, gold or platinum.

The contact elements 31, 32 are applied using a shadow mask 6.

The contact elements 31, 32 are formed by depositing or vapor depositing a contact metal 35 from the direction of the shadow mask 6.

In view of the main surface 10, the contact elements 31, 32 each have a width of about 50 μm.

In a further step, the semiconductor layer sequence 1 is locally thermally annealed (FIG. 2). The main surface 10 is irradiated with radiation of a first wavelength range 51 from a direction of the first and second contact elements 31, 32. The radiation of the first wavelength range 51 is absorbed by the first and second contact elements 31, 32. The semiconductor layer sequence 1 and preferably the substrate 2 are transparent to radiation of the first wavelength range. For example, the first wavelength range 51 comprises radiation in the visible range of the electromagnetic spectrum and/or in the IR range. For example, the first wavelength range comprises wavelengths of at least 450 nm or at least 400 nm. In particular, the main surface 10 is irradiated over a large area with radiation of the first wavelength range 51.

Due to absorption of radiation of the first wavelength range 51 by the contact elements 31, 32, the contact elements 31, 32 are heated to at least 300° C. or at least 350° C. Due to the heating of the contact elements 31, 32, the main surface 10 respectively the wafer 100 is thermally annealed in contact regions 11, 12. The annealing takes place locally. The contact regions 11, 12, like the contact elements 31, 32, are formed at a distance from each other.

Advantageously, the local thermal annealing takes place only in the region of the contact elements 31, 32. A mean temperature of the contact elements 31, 32 is at least 50° C. higher than a mean temperature of the semiconductor layer sequence 1. The mean temperature of the semiconductor layer sequence 1 outside the contact regions 11, 12 is, for example, at most 200° C. or at most 100° C.

Deviating from the method step shown in FIG. 2, it is also possible that the radiation of the first wavelength range is irradiated from the direction of the substrate 2.

In a further step of the method, a first electrical potential 41 is applied to a first contact element 31 and a second electrical potential 42 is applied to a second contact element 32 (FIG. 3). The potentials 41, 42 are each applied, for example, by means of a needle. The potentials 41, 42 differ from each other. The first electrical potential 41 is applied in such a way that a breakthrough 90 is formed in the semiconductor layer sequence 1 in the region of the first contact elements 31. For example, the first and second contact elements 31, 32 are arranged at a p-type layer of the semiconductor layer sequence 1. The breakthrough is formed in the p-type layer and the active zone. Electrons can pass from the first contact element 31 to an n-type layer of the semiconductor layer sequence 1 through the breakthrough. The n-type layer is arranged between the active zone and the substrate 2. Thus, it is possible to supply the active zone of the semiconductor layer sequence 1 with current such that electromagnetic radiation is generated in the active zone. This enables a functional test of the semiconductor layer sequence 1.

In a further method step, the electrical contact elements 31, 32 are removed (FIG. 4). The electrical contact elements 31, 32 are removed by wet chemical etching. The etchant used is, for example, aqua regia.

The method illustrated in FIGS. 5 to 9 differs from the method illustrated in FIGS. 1 to 4 in that an electrical contact layer 36 is applied flat over the surface of the main surface 10 before the first and second contact elements 31, 32 are applied (FIG. 5). The contact layer 36 completely covers the main surface 10. The contact layer 36 is applied by means of sputtering. The contact layer 36 is formed with ITO. The contact layer 36 has a thickness between 10 nm and 20 nm inclusive.

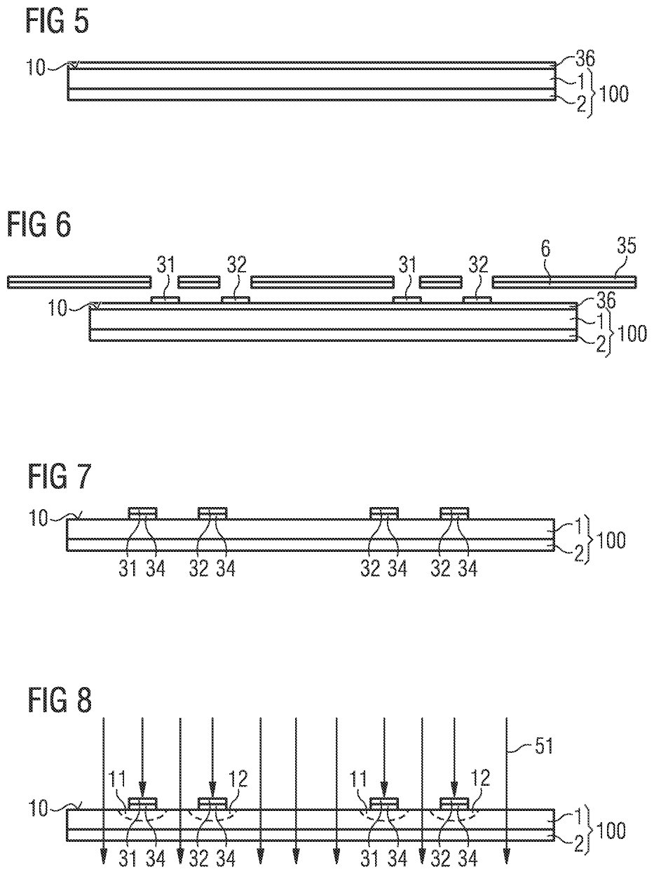

On a side of the contact layer 36 facing away from the main surface 10, the first and second electrical contact elements 31, 32 are applied (FIG. 6). The contact elements 31, 32 are applied using the same methods as described in connection with FIG. 1.

In a further method step, the contact layer 36 is removed in regions that are free of the contact elements 31, 32 as seen from the main surface 10 (FIG. 7). The remaining parts of the contact layer 36 form an intermediate layer 34. For example, the contact layer 36 is removed by wet chemical etching.

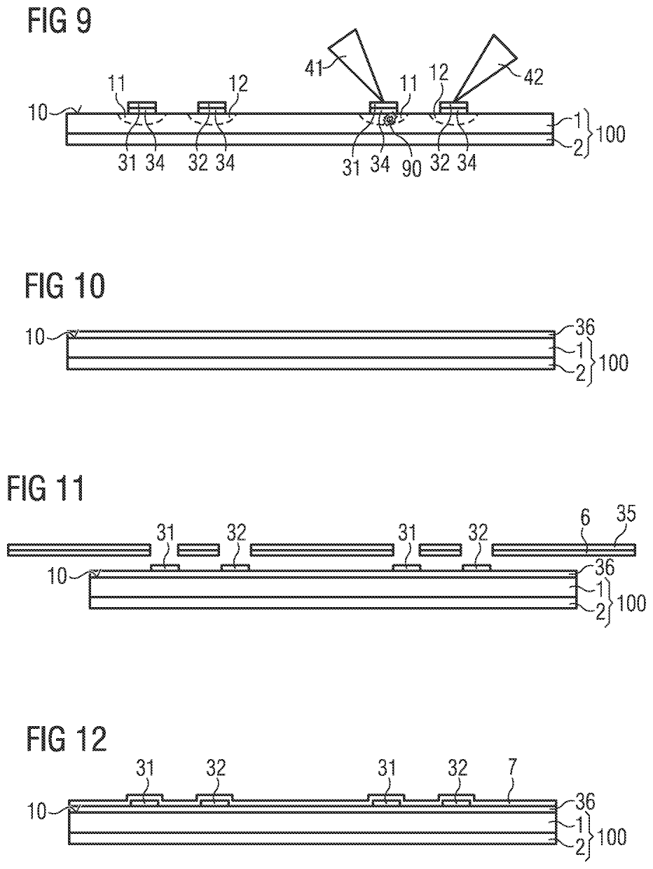

In a further step, the semiconductor layer sequence 1 is locally annealed (FIG. 8). Subsequently, a first electrical potential 41 is applied to a first contact element 31 and an electrical potential 42 is applied to a second contact element 42 (FIG. 9). The annealing of the semiconductor layer sequence 1 and the application of the potentials 41, 42 is carried out as explained in connection with FIGS. 2 and 3.

In the method of FIGS. 10 to 19, a wafer 100 comprising a substrate 2 and a semiconductor layer sequence 1 disposed on the substrate 2 is provided. An electrical contact layer 36 is deposited on a main surface 10 of the semiconductor layer sequence 1 (FIG. 10). The contact layer 36 is applied by means of sputtering. The contact layer 36 is formed with ITO, for example. The contact layer 36 has a thickness between 10 nm and 20 nm inclusive.

The substrate 2 is a sapphire substrate. The semiconductor layer sequence 1 is epitaxially grown on the substrate 2, for example.

The semiconductor layer sequence 1 is arranged to generate electromagnetic radiation, for example. The semiconductor layer sequence 1 includes an active zone between a first semiconductor layer and a second semiconductor layer. The semiconductor layer sequence 1 is based on a III-V semiconductor material, such as GaN or InGaN. The first semiconductor layer is, for example, an n-type GaN- or InGaN-based layer or layer sequence. The second semiconductor layer is, for example, a p-type GaN- or InGaN-based layer or layer sequence. The active zone is, for example, a GaN- or InGaN-based quantum well structure or multiquantum well structure.

Subsequent to the application of the contact layer 36, the semiconductor layer sequence 1 is annealed in a region on the main surface 10, wherein the region on the main surface 10 comprises at least one region in which first and second contact elements 31 are subsequently applied. In particular, the entire semiconductor layer sequence 10 is annealed. For example, the wafer 100 is heated to a temperature of at least 300° C. or at least 350° C. for this purpose.

First and second electrical contact elements 31, 32 are disposed on a side of the electrical contact layer 36 opposite the main surface 10 (FIG. 11).

The contact elements 31, 32 each comprise one or more metals. The metals are, for example, titanium, chromium, gold or platinum.

The contact elements 31, 32 are applied using a shadow mask 6. The contact elements 31, 32 are produced by depositing or vapor-depositing a contact metal 35 from the direction of the shadow mask 6.

In view of the main surface 10, the contact elements 31, 32 each have a width of about 50 μm.

A protective layer 7 is applied to a side of the contact layer 36 facing away from the main surface 10 (FIG. 12). The protective layer 7 completely covers the contact layer 36 and the first and second contact elements 31, 32 in view of the main surface 10. The protective layer 7 is formed with Al₂O₃ and applied by means of atomic layer deposition. The thickness of the protective layer 7 is between 30 nm and 40 nm inclusive. In particular, the protective layer 7 is configured to protect the contact layer 36.

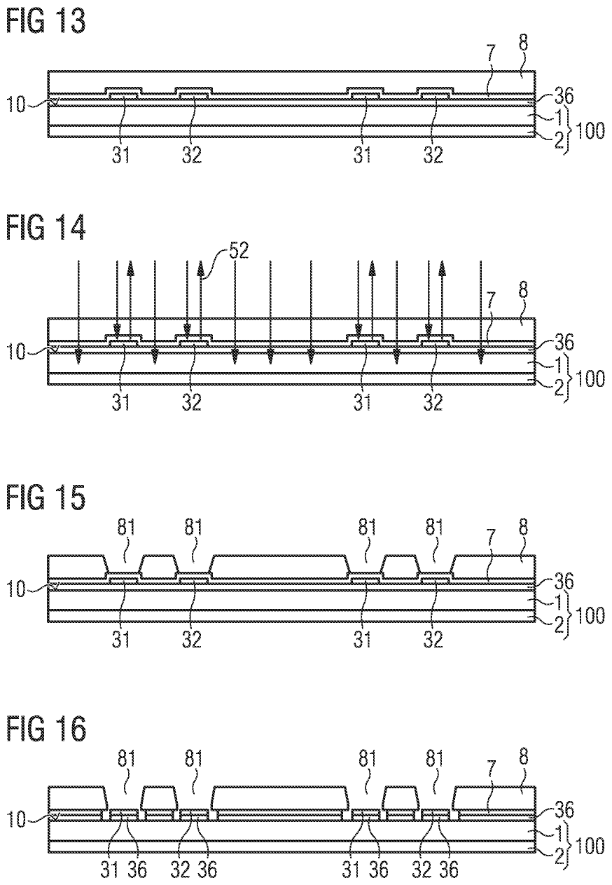

In a further step, a mask layer 8 is arranged on a side of the protective layer 7 facing away from the contact layer 36 (FIG. 13). The mask layer 8 is a positive photoresist.

In a further method step, the main surface 10 is irradiated over its area with radiation of a second wavelength range 52 from a direction of the mask layer 8 (FIG. 14). That is, the radiation of the second wavelength range 52 is unfocused. The radiation of the second wavelength range 52 is, for example, UV radiation. The second wavelength range 52 comprises, for example, wavelengths smaller than 380 nm or smaller than 400 nm. As shown in FIG. 14, radiation of the second wavelength range 52 is reflected at the metallic contact elements 31, 32. Due to this reflection, radiation of the second wavelength range 52 passes the photoresist twice in regions where the mask layer 8 covers the first and second contact elements 31, 32. In these regions, increased exposure of the photoresist takes place.

In a further method step, the mask layer 8 is structured (FIG. 15). The photoresist is developed for this purpose. Openings 81 are formed in regions where the photoresist has been exposed more strongly. The openings 81 are thus formed in regions where the mask layer 8 covered the contact elements 31, 32 before structuring. The protective layer 7 is exposed in the openings 81.

In an optional method step not shown, the mask layer 8 is thinned by means of an oxygen plasma. The openings 81 can also be widened in this process.

In view of the main surface 10, the openings 81 have a width which, at their smallest point, corresponds substantially to the width of the contact elements 31, 32. For example, the width of the openings 81 at this point is at most 10% or at most 5% greater than the width of the contact elements 31, 32.

In a further method step, the protective layer 7 is removed in the region of the contact elements 31, 32 (FIG. 16). After removal of the protective layer 7, the contact elements 31, 32 are preferably free of the protective layer 7 on all sides. The protective layer 7 is removed by a wet chemical etching process using H₃PO₄ as etchant.

In a further method step, the contact layer 36 is removed in the regions of the openings 81 and in regions that are free of the contact elements 31, 32 (FIG. 16). The contact layer 36 is removed in these regions, for example, by wet chemical etching using HCl as etchant.

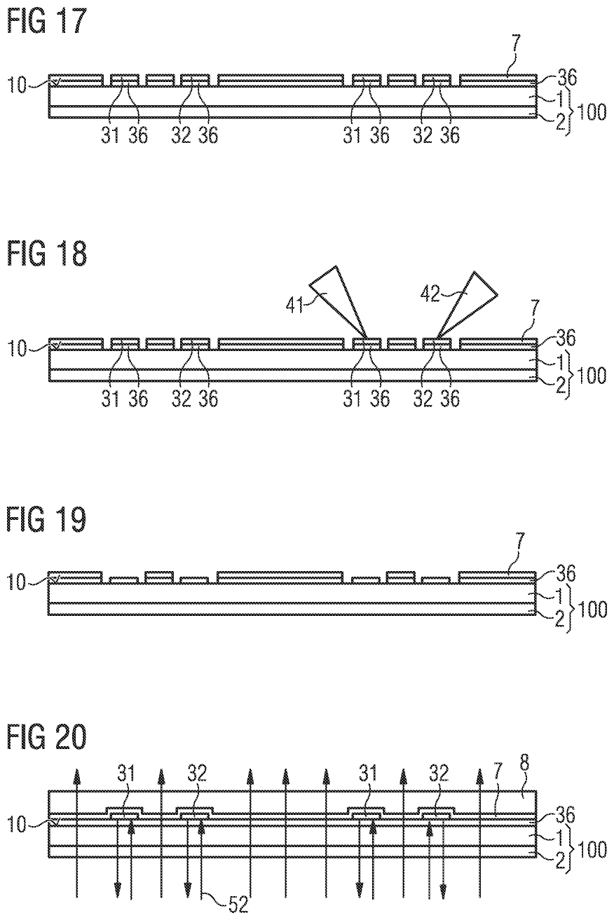

In a further method step, the mask layer 8 is removed (FIG. 17). The mask layer 8 is removed, for example, with an organic solvent or by ashing.

In a further method step, a first electrical potential 41 is applied to a first contact element 31 and a second electrical potential 42 is applied to a second electrical contact element 32 (FIG. 18). The application of the electrical potentials 41, 42 and the performance of the function test are carried out as explained in connection with FIG. 3.

In an optional method step, the first and second contact elements 31, 32 are removed (FIG. 19). The removal of the contact elements 31, 32 is carried out, for example, as explained in connection with FIG. 4.

FIG. 20 illustrates a method step as shown in connection with FIG. 14, with the difference that the radiation of the second wavelength range 52 is irradiated from a direction of the substrate 2. The mask layer 8 is preferably formed with a negative photoresist. The contact elements 31, 32 cause shading of regions of the mask layer 8 which, in view of the main surface 10, cover the contact elements 31, 32. When structuring the mask layer 8 by means of developing the negative photoresist, those regions of the mask layer 8 are removed which have been exposed to a lesser extent than remaining regions of the mask layer 8.

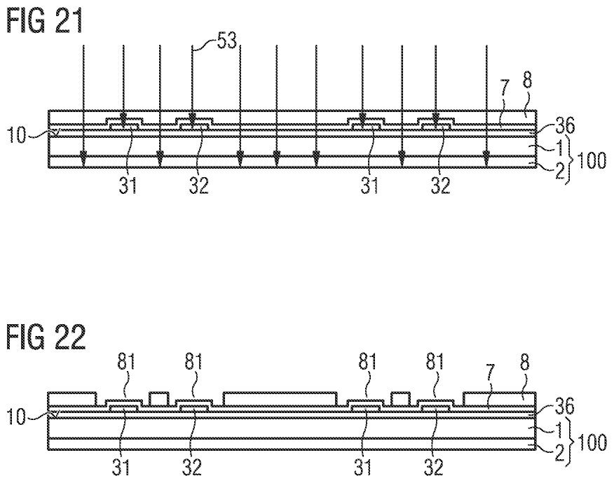

FIGS. 21 and 22 illustrate method steps in which, in contrast to the method steps illustrated in FIGS. 10 to 19, a mask layer 8 that can be thermally structured is used. For example, the mask layer 8 is formed with a material having an evaporation temperature or a sublimation temperature of less than 300° C. For example, the mask layer 8 is formed with a thermoplastic.

When the mask layer 8 is structured, the main surface 10 is irradiated with radiation of a third wavelength range 53 (FIG. 21). The irradiation takes place from a direction of the mask layer 8. The radiation of the third wavelength range 53 is absorbed by the contact elements 31, 32. For example, the third wavelength range 53 comprises radiation in the visible range of the electromagnetic spectrum and/or in the IR range. For example, the first wavelength range comprises wavelengths of at least 450 nm or at least 400 nm.

Due to absorption of the radiation of the third wavelength range 53 by the contact elements 51, the contact elements are heated up to, for example, 300° C. or 350° C. At such a temperature, the mask layer 8 evaporates or sublimates in regions which, in plan view of the main surface 10, cover the contact elements 31, 32 (FIG. 22). Openings 81 are formed in these regions.

Optionally, residues of the mask layer 8 in the openings can be removed by means of an oxygen plasma. It is possible for the mask layer 8 to be thinned in the process.

The invention is not limited to the exemplary embodiments by the description based thereon. Rather, the invention encompasses any new feature as well as any combination of features, which includes in particular the combination of features in the patent claims, even if this feature or combination itself is not explicitly stated in the patent claims or exemplary embodiments.

This patent application claims the priority of German patent application 10 2021 108 756.2, the disclosure content of which is hereby incorporated by reference.

1.-16. (canceled)

17. A method for performing a functional test on a wafer, the method comprising:
providing the wafer with a semiconductor layer sequence arranged on a substrate;
attaching at least one first contact element to a main surface of the semiconductor layer sequence facing away from the substrate;
attaching at least one second contact element to the main surface of the semiconductor layer sequence at a distance to the first contact element; and
applying a first electrical potential to the first contact element and a second electrical potential to a second contact element, wherein the first electrical potential and the second electrical potential are different from each other,
wherein, by locally annealing the semiconductor layer sequence, a first contact region is formed in a region of the first contact element and a second contact region, which is spaced apart from the first contact region, is formed in a region of the second contact element.

18. The method according to claim 17, wherein the semiconductor layer sequence is annealed before the first contact element is attached, wherein annealing is carried out at least in a region at the main surface where the first contact element and/or the second contact element is subsequently attached.

19. The method according to claim 17, wherein the semiconductor layer sequence is locally annealed in a region of the first contact element and/or the second contact element.

20. The method according to claim 17,
wherein a contact layer is applied to the main surface before annealing,
wherein the first contact element is applied in places to the contact layer,
wherein a protective layer followed by a mask layer is applied on a side of the contact layer facing away from the semiconductor layer sequence,
wherein the mask layer is patterned thereby forming openings in the mask layer so that the contact element is not covered by the mask layer in view of the main surface and so that the protective layer is exposed in the openings,
wherein the protective layer is removed in regions of the openings so that the contact layer and the first contact element are exposed,
wherein the contact layer is removed in regions of the openings, which are free of the first contact element in view of the main surface, and
wherein the mask layer is completely removed.

21. The method according to claim 20,
wherein the mask layer is a photoresist layer,
wherein the photoresist is structured by radiation of a second wavelength range, and
wherein the radiation of the second wavelength range is reflected at the first contact element.

22. The method according to claim 21, wherein the second wavelength range is selected such that the semiconductor layer sequence is transparent for radiation of the second wavelength range.

23. The method according to claim 21, wherein the radiation of the second wavelength range is irradiated from a direction of a side of the semiconductor layer sequence facing away from the mask layer.

24. The method according to claim 20, wherein the mask layer is thermally structured,
wherein the semiconductor layer sequence is irradiated with radiation of a third wavelength range,
wherein the radiation of the third wavelength range is absorbed by the first contact element, and
wherein the mask layer vaporizes or melts in regions covering the first contact element.

25. The method according to claim 24, wherein the third wavelength range is selected such that semiconductor layer sequence is transparent for the radiation of the third wavelength range.

26. The method according to claim 24, wherein the radiation of the third wavelength range is irradiated from a direction of a side of the semiconductor layer sequence facing away from the mask layer.

27. The method according to claim 17, wherein the second contact element is formed simultaneously with the first contact element by the same process.

28. The method according to claim 17,
wherein the semiconductor layer sequence is locally annealed by radiation of a first wavelength range,
wherein the radiation of the first wavelength range is absorbed by at least a part of the first contact element, and
wherein an average temperature of the semiconductor layer sequence in the first contact region during annealing is at least 50° C. higher than an average temperature of the semiconductor layer sequence outside the first contact region.

29. The method according to one claim 17, wherein a first wavelength range is selected such that the semiconductor layer sequence is transparent for radiation of the first wavelength range.

30. The method according to claim 28, wherein the main surface is irradiated with the radiation of the first wavelength range from a direction of a side of the semiconductor layer sequence facing away from the contact elements.

31. The method according to claim 17,
wherein an intermediate layer is formed between the first contact element and the semiconductor layer sequence,
wherein material for the intermediate layer is applied as a contact layer flat on the main surface of the semiconductor layer sequence,
wherein the first contact element is applied in places to the contact layer, and
wherein the contact layer is removed in regions that are free of the first contact element in view of the main surface.

32. The method according to claim 17, wherein all contact elements are removed in a further method step.

33. The method according to claim 17, wherein a position of each contact element on the main surface of the semiconductor layer sequence is selected by lithography or based on a position marker.

34. A wafer comprising:
a substrate and a semiconductor layer sequence arranged on the substrate and having a main surface facing away from the substrate,
wherein at least one first electrical contact element and at least one second electrical contact element apart from the first electrical contact element are arranged at the main surface,
wherein the semiconductor layer sequence has a locally elevated temperature in a region of the first contact element and the second contact element,
wherein the first contact element is configured to receive a first electrical potential,
wherein the second contact element is configured to receive a second electrical potential, and
wherein the first and second electrical potential are different from each other.
